(19) United States
(12) Patent Application Publication
(10) Pub. No.: US 2017/0148854 A1
(43) Pub. Date: May 25, 2017

(54) OLED Display Panel

(71) Applicant: EverDisplay Optronics (Shanghai) Limited, Shanghai (CN)

(72) Inventor: Xin Mou, Shanghai (CN)

(21) Appl. No.: 15/358,981

(22) Filed: Nov. 22, 2016

(30) Foreign Application Priority Data
Nov. 25, 2015 (CN) 201510834195.4

(51) Int. Cl. H01L 27/32; H01L 51/00; H01L 51/50

(52) U.S. Cl. CPC H01L 27/3211; H01L 51/508; H01L 51/5096; H01L 51/0011; H01L 51/001; H01L 51/5012; H01L 51/5016; H01L 51/5072; H01L 2251/5376; H01L 51/0072

(57) ABSTRACT

The present invention discloses an OLED display panel, which is achieved by providing an electron cushion layer between the blue sub-pixel light emitting layer and the electron transport layer to prevent the accumulation of electrons on the interface of the emitting layer, thus the lifetime of the blue sub-pixel of the OLED panel and the phenomenon of offset of white chromaticity coordinate of the OLED display panel caused by excessive attenuation of luminance of the blue sub-pixel are improved, so that the lifetime of the OLED display panel is increased; further the present invention uses different materials of the electron transport layer for RGB sub-pixels, by virtue of selecting the material of the electron transport layer which is most favorable to the lifetime of RGB sub-pixels according to the material of each sub-pixel light emitting layer, to improve the lifetime of the blue sub-pixel of the OLED panel.

### CROSS-REFERENCE TO RELATED APPLICATIONS

The present application claims priority to and the benefit of Chinese Patent Application No. CN 201510834195.4, filed on Nov. 25, 2015, the entire content of which is incorporated herein by reference.

### BACKGROUND OF THE INVENTION

### Field of the Invention

The present invention relates to the field of semiconductor manufacturing technology, more particularly, to an OLED display panel.

### Description of the Related Art

Lifetime of the blue sub-pixel of the OLED display panel is far worse than the red sub-pixel and the green sub-pixel, which would result the offset of the white chromaticity coordinate after the OLED display panel being used for a period of time, and would affect the OLED display quality, thus the application of the OLED in the field needing higher requirement for lifetime is further restricted such as TV, on-board.

What is obvious in FIG. 1 is that with increasing use of time, the attenuation of luminance of the blue sub-pixel 3 is greater than the red sub-pixel 1 and the green sub-pixel 2, which further leads to the attenuation of luminance of the white light 4; FIG. 2 illustrates that, with increasing use of time, the white chromaticity coordinate offsets, the change of the white chromaticity coordinate after the OLED device been used about 1000 hours is as the following table:

| | 0 hour | | 1000 hours | | ΔCIE-xy | |
|---|---|---|---|---|---|---|
| | chromaticity coordinate | | | | | |
| | CIE-x | CIE-y | CIE-x | CIE-y | ΔCIE-x | ΔCIE-y |
| white light | 0.2998 | 0.3415 | 0.3108 | 0.358 | 0.011 | 0.0165 |

However existing common method for improving the lifetime of the blue sub-pixel is configuring different aperture ratios of RGB sub-pixels; since the level of lifetime is green>red>blue generally, so the size of the aperture ratio is configured to blue>red>green, even so it still can't completely solve the problem of the service life of the blue light is far worse than the red light and the green light.

Therefore, improving lifetime of the blue sub-pixel of the OLED display panel and improving the phenomenon of offset of white chromaticity coordinate of the OLED display panel caused by excessive attenuation of luminance of the blue sub-pixel becomes the research direction those skilled in the art dedicated to.

### SUMMARY OF THE INVENTION

In view of the above-mentioned problems, the present application discloses an OLED display panel, comprising a luminescent material layer and an electron transport layer (ETL) positioned on the luminescent material layer, wherein

the luminescent material layer comprises a red sub-pixel light emitting layer, a green sub-pixel light emitting layer and a blue sub-pixel light emitting layer; and

an electron cushion layer (ECL) disposed between the blue sub-pixel light emitting layer and the electron transport layer to limit the accumulation of electrons between the blue sub-pixel light emitting layer and the electron transport layer.

In the above-mentioned OLED display panel, a material of the electron cushion layer is organic material.

In the above-mentioned OLED display panel, a material of the electron cushion layer is the same as the host material of the electron transport layer.

In the above-mentioned OLED display panel, the thickness of the electron cushion layer is between 5 angstroms to 500 angstroms.

The above-mentioned OLED display panel further comprises a substrate, an anode, a hole injection layer, a hole transport layer, an electron injection layer and a cathode;

wherein the anode is positioned between the substrate and the hole injection layer, the hole transport layer is positioned between the hole injection layer and the luminescent material layer, the electron injection layer covers an upper surface of the electron transport layer, and the cathode covers an upper surface of the electron injection layer.

In the above-mentioned OLED display panel, a material of the blue sub-pixel light emitting layer is fluorescent material, and a material of the green sub-pixel light emitting layer and a material of the red sub-pixel light emitting layer are both phosphor material.

In the above-mentioned OLED display panel, FFM is used to manufacture the electron cushion layer.

The present invention further provides an OLED display panel, comprising a luminescent material layer and an electron transport material layer positioned on the luminescent material layer; the luminescent material layer comprising a red sub-pixel light emitting layer, a green sub-pixel light emitting layer and a blue sub-pixel light emitting layer;
wherein the electron transport material layer comprises a first electron transport layer covering an upper surface of the red sub-pixel light emitting layer, a second electron transport layer covering an upper surface of the green sub-pixel light emitting layer and a third electron transport layer covering an upper surface of the blue sub-pixel light emitting layer;
wherein a material of the third electron transport layer is different from the material of the first electron transport layer and/or the second electron transport layer.

In the above-mentioned OLED display panel, the material of the first electron transport layer is the same as the material of the second electron transport layer.

In the above-mentioned OLED display panel, the material of the blue sub-pixel light emitting layer is fluorescent material, the material of the green sub-pixel light emitting layer and the red sub-pixel light emitting layer is phosphor material.

In the above-mentioned OLED display panel, the material of the third electron transport layer is PO₁₄.

In the above-mentioned OLED display panel, the material of the first electron transport layer and the material of the second electron transport layer are both TPBI.

The above-mentioned OLED display panel further comprises a substrate, an anode, a hole injection layer, a hole transport layer, an electron injection layer and a cathode;
wherein the anode is positioned between the substrate and the hole injection layer, the hole transport layer is positioned between the hole injection layer and the luminescent material layer, the electron injection layer covers the upper surface of the electron transport layer, the cathode covers the upper surface of the electron injection layer.

The above-mentioned invention has the advantages and the beneficial effects as follows:

The present invention discloses an OLED display panel with an improved lifetime of blue sub-pixel of OLED display panel, which is achieved by configuring an electron cushion layer between the blue sub-pixel light emitting layer and the electron transport layer to prevent the accumulation of electrons on the interface of the emitting layer, so that the lifetime of the OLED display panel is increased; further the present invention uses different materials of the electron transport layer through RGB sub-pixels, and by virtue of selecting the material of the electron transport layer which is most favorable to the lifetime of RGB sub-pixels according to the material of each sub-pixel light emitting layer, the lifetime of the blue sub-pixel of the OLED panel is improved and the lifetime of the OLED display panel is increased.

### BRIEF DESCRIPTIONS OF THE DRAWINGS

The accompanying drawings, together with the specification, illustrate exemplary embodiments of the present disclosure, and, together with the description, serve to explain the principles of the present invention.

FIG. 1 is a schematic diagram that the luminance of RGB sub-pixels changes over time in the background of the present invention;

FIG. 2 is a schematic diagram that the white chromaticity coordinate changes over time in the background of the present invention;

FIG. 3 is a structure diagram of the OLED display panel in embodiment 1 of the present invention;

FIG. 4 is a schematic diagram that the luminance of the blue sub-pixel changes over time in the cases of with and without ECL in embodiment 1 of the present invention;

FIG. 5 is a structure diagram of the OLED display panel in embodiment 2 of the present invention.

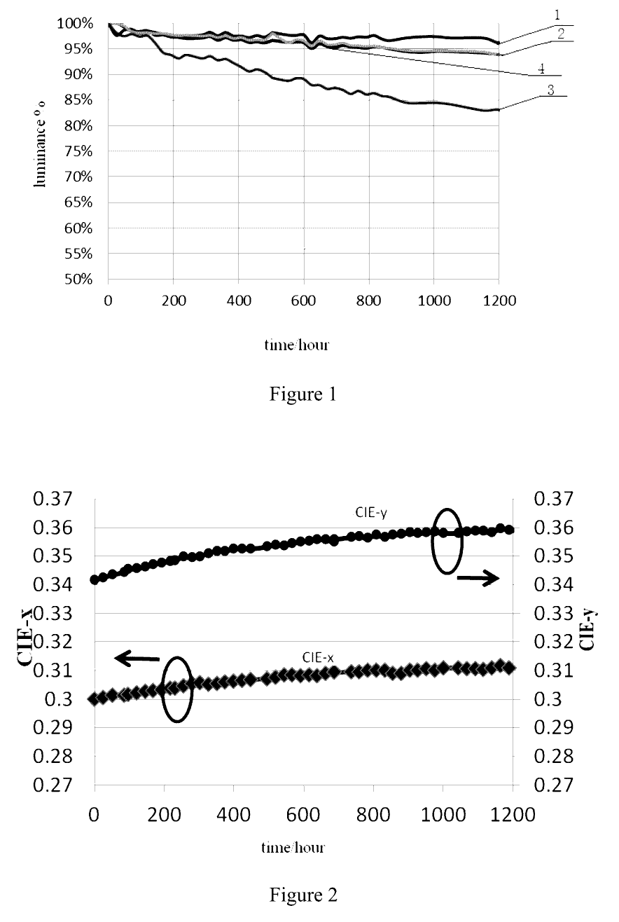

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

The present invention provides an OLED display panel comprising a luminescent material layer and an electron transport layer positioned on the luminescent material layer, the luminescent material layer comprises a red sub-pixel light emitting layer, a green sub-pixel light emitting layer and a blue sub-pixel light emitting layer; wherein an electron cushion layer is also disposed between the blue sub-pixel light emitting layer and the electron transport layer to limit the accumulation of electrons between the blue sub-pixel light emitting layer and the electron transport layer.

In a preferable embodiment of the present invention, the material of the electron cushion layer is organic material.

In a preferable embodiment of the present invention, the material of the electron cushion layer is the same as the host material (ETL-Host) of the electron transport layer.

In a preferable embodiment of the present invention, the thickness of the electron cushion layer is between 5 angstroms to 500 angstroms.

In a preferable embodiment of the present invention, the OLED display panel further comprises a substrate, an anode, a hole injection layer, a hole transport layer, an electron injection layer and a cathode; wherein the anode is positioned between the substrate and the hole injection layer; the hole transport layer is positioned between the hole injection layer and the luminescent material layer; the electron injection layer covers the upper surface of the electron transport layer; the cathode covers the upper surface of the electron injection layer.

In a preferable embodiment of the present invention, the material of the blue sub-pixel light emitting layer is fluorescent material, and the material of the green sub-pixel light emitting layer and the material of the red sub-pixel light emitting layer are both phosphor material.

In a preferable embodiment of the present invention, FMM (Fine Metal Mask) is used to manufacture the electron cushion layer.

The present invention further provides an OLED display panel comprising: a luminescent material layer and an electron transport material layer positioned on the luminescent material layer, the luminescent material layer comprises a red sub-pixel light emitting layer, a green sub-pixel light emitting layer and a blue sub-pixel light emitting layer; the electron transport material layer comprises a first electron transport layer covering the upper surface of the red sub-pixel light emitting layer, a second electron transport layer covering the upper surface of the green sub-pixel light emitting layer, and a third electron transport layer covering the upper surface of the blue sub-pixel light emitting layer; wherein the material of the third electron transport layer is different from the material of the first electron transport layer and/or the material of the second electron transport layer; in other words, the material of the third electron transport layer is different from at least one of the material of the first electron transport layer and the second electron transport layer; further the material of the electron transport layer can be selected of the material which is most favorable to the lifetime of the sub-pixel light emitting layer on basis of the different materials of sub-pixel light emitting layers to maximize the lifetime of RGB sub-pixels; in the embodiment of the present invention, the material of the first electron transport layer may be the same as or different from the material of the second electron transport layer, which does not affect the purpose of the present invention.

In a preferable embodiment of the present invention, the electron cushion layer disposed between the blue sub-pixel light emitting layer and the third electron transport layer limits the accumulation of electrons between the blue sub-pixel light emitting layer and the electron transport layer.

In a preferable embodiment of the present invention, the material of the blue sub-pixel light emitting layer is fluorescent material, and the material of the green sub-pixel light emitting layer and the red sub-pixel light emitting layer is phosphor material.

In a preferable embodiment of the present invention, the material of the third electron transport layer is PO₁₄.

In a preferable embodiment of the present invention, the material of the first electron transport layer and the material of the second electron transport layer is TPBI.

In a preferable embodiment of the present invention, the OLED display panel further comprises a substrate, an anode, a hole injection layer, a hole transport layer, an electron injection layer and a cathode; wherein the anode is positioned between the substrate and the hole injection layer; the hole transport layer is positioned between the hole injection layer and the luminescent material layer; the electron injection layer covers the upper surface of the electron transport layer; and the cathode covers the upper surface of the electron injection layer.

The further elaboration of the present invention in conjunction with specific embodiments is as below.

### Embodiment 1

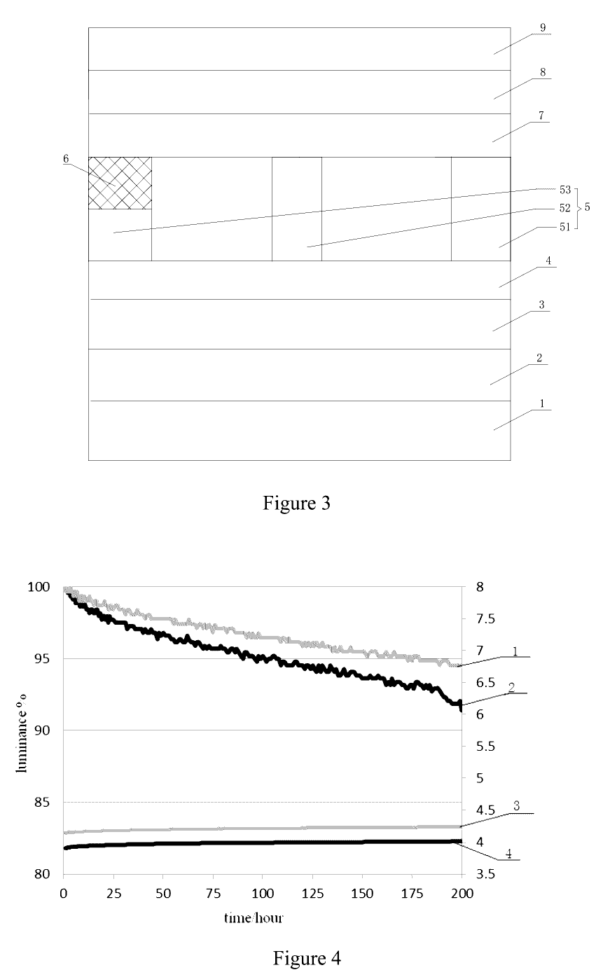

As shown in FIG. 3, the embodiment relates to an OLED display panel comprising a luminescent material layer 5 and an electron transport layer 7 positioned on the luminescent material layer 5, and further comprises a substrate 1, an anode 2, a hole injection layer 3, a hole transport layer 4, an electron injection layer 8 and a cathode 9; wherein the anode 2 is positioned between the substrate 1 and the hole injection layer 3; the hole transport layer 4 is positioned between the hole injection layer 3 and the luminescent material layer 5; the electron injection layer 8 covers the upper surface of the electron transport layer 7; the cathode 9 covers the upper surface of the electron injection layer 8.

The aforementioned luminescent material layer 5 comprises a red sub-pixel light emitting layer 51, a green sub-pixel light emitting layer 52 and a blue sub-pixel light emitting layer 53; wherein an electron cushion layer 6 is further disposed between the blue sub-pixel light emitting layer 53 and the electron transport layer 7 to limit the accumulation of electrons between the blue sub-pixel light emitting layer 53 and the electron transport layer 7; further, the material of the electron cushion layer 6 is organic material, such as PO₁₄; the electron cushion layer 6 may use the material which is the same as the host material of the electron transport layer 7; for example, if the material of the electron transport layer 7 is TPBI, the material of the electron cushion layer 6 may also use TPBI, and of course different materials may be used as long as the materials can limit the accumulation of electrons on the interface between the blue sub-pixel light emitting layer 53 and the electron transport layer 7 and improve the lifetime of the blue sub-pixel of the OLED panel. Preferably, the thickness of the electron cushion layer is between 5 angstroms to 500 angstroms (such as 5 angstroms, 100 angstroms, 250 angstroms or 500 angstroms and so on).

In the embodiment the material of the blue sub-pixel light emitting layer 53 is fluorescent material, and the material of the green sub-pixel light emitting layer 52 and the red sub-pixel light emitting layer 51 is phosphor material.

In the embodiment, the electron cushion layer (ECL) can be vapor-deposited by a FMM of the blue sub-pixel light emitting layer, and then a CMM (Common Metal Mask) is used to vapor-deposit the electron transport layer (ETL); specifically, traditional vacuum evaporation method is used to manufacture the electron cushion layer 6; since the electron cushion layer 6 is only positioned between the blue sub-pixel light emitting layer 53 and the electron transport layer 7, so a FMM is needed for vapor deposition; the opening shape and the size of the FMM is consistent with the FMM of the blue sub-pixel light emitting layer 53. The FMM having the same opening shape and the same size as the FMM of the blue sub-pixel light emitting layer 53 is transferred into an organic vacuum chamber, and the glass substrate vapor-deposited with the blue sub-pixel light emitting layer 53 is transferred into the chamber, the FMM and the glass substrate both have alignment marks, an aligning mechanism is used to align the opening of the FMM to the blue sub-pixel area; when the pressure of the vacuum chamber reaches 10⁻⁵ Pa or more, a PO₁₄ thin-film of 5 nm thickness is deposited by thermal evaporation, the rate is maintained constant during the vapor deposition, the uniformity of the thin-film is maintained within 5%, and the rate is 0.3⁻⁵ nm/s (based on the capacity and tact time).

The following further illustrates the present invention combined with experimental data.

The device with the ECL of the embodiment is compared with the device without the ECL, wherein the material of the ECL is the same as the host material of the ETL (ETL-Host). Photoelectric properties of the blue device under the current density of 15 mA/cm² and the green device under 12000 nits and the red device under 3000 nits are listed below.

| | | | current | | | |
|---|---|---|---|---|---|---|
| color of | | drive | efficiency/ | | | |
| device | material | voltage/V | cd/A | CIE-x | CIE-y | LT95/hour |
| blue | no ECL | 4.13 | 7.72 | 0.1323 | 0.0609 | 95 |
| | ECL | 4.27 | 6.88 | 0.1320 | 0.0603 | 172 |
| green | no ECL | 4.1 | 106.01 | 0.2351 | 0.7127 | 297 |
| | ECL | 4.18 | 104.07 | 0.2355 | 0.7155 | 50 |
| red | no ECL | 3.36 | 60.01 | 0.6625 | 0.3372 | 900 |
| | ECL | 3.39 | 55.94 | 0.6570 | 0.3427 | 910 |

It can be seen from the table and FIG. 4, the attenuation of the curve 1 that the luminance percentage of the blue device with the ECL changes over time is slower than the attenuation of the curve 2 that the luminance percentage of the blue device without the ECL; the attenuation degree of the voltage 3 of the blue device with the ECL changing over time is consistent with the voltage 4 of the blue device without the ECL; the lifetime LT95 of the blue device with the ECL is 172 hours, yet the lifetime LT95 of the device without the ECL is 95 hours, so the LT95 of the device is increased 1.81 times when the ECL layer is increased, which confirms that the increasing ECL helps enhancing the lifetime of the device. However the lifetime of the green device sharply reduces after increasing the ECL layer, the lifetime of the red device is changeless after increasing the ECL layer; which confirms that it is the best choice to add the electron cushion layer between the blue sub-pixel light emitting layer and the electron transport layer, which can effectively enhance the lifetime of the OLED display panel.

The experimental data proves that the scheme can increase the lifetime of the blue sub-pixel at least 1.5 times (the increment is depended on the material of the ETL).

### Embodiment 2

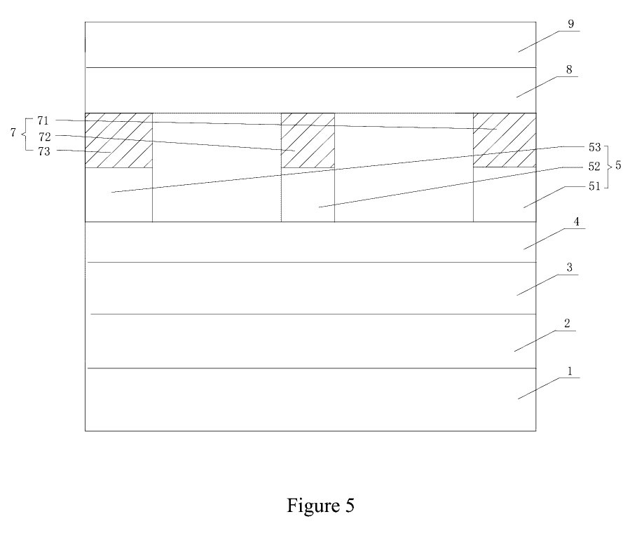

As shown in FIG. 5, the embodiment relates to an OLED display panel and comprises: a luminescent material layer 5 and an electron transport material layer 7 positioned on the luminescent material layer 5, and further comprises a substrate 1, an anode 2, a hole injection layer 3, a hole transport layer 4, an electron injection layer 8 and a cathode 9; wherein the anode 2 is positioned between the substrate 1 and the hole injection layer 3; the hole transport layer 4 is positioned between the hole injection layer 3 and the luminescent material layer 5; the electron injection layer 8 covers the upper surface of the electron transport material layer 7; and the cathode 9 covers the upper surface of the electron injection layer 8.

The luminescent material layer 5 comprises a red sub-pixel light emitting layer 51, a green sub-pixel light emitting layer 52 and a blue sub-pixel light emitting layer 53; the electron transport material layer 7 comprises a first electron transport layer 71 covering the upper surface of the red sub-pixel light emitting layer 51, a second electron transport layer 72 covering the upper surface of the green sub-pixel light emitting layer 52 and a third electron transport layer 73 covering the upper surface of the blue sub-pixel light emitting layer 53; wherein the material of the third electron transport layer 73 is different from the material of the first electron transport layer 71 and/or the second electron transport layer 72, i.e. the material of the third electron transport layer 73 is different from at least one of the materials of the first electron transport layer 71 and the second electron transport layer 72; in the embodiment of the present invention, the FMM is used to vapor-deposit the electron transport material layer 7 to benefit to use the material of the ETL which is the best for and optimizes the lifetime of RGB.

In the embodiment of the present invention, the material of the blue sub-pixel light emitting layer 53 is fluorescent material, the material of the green sub-pixel light emitting layer 52 and the material of the red sub-pixel light emitting layer 51 are both phosphor material; since the existing materials for the electron transport layer that satisfy the phosphorescence and fluorescence and both have high lifetime is less, so RGB sub-pixels may use different materials for the electron transport layer, thus choosing the material for the electron transport layer that is most beneficial to the lifetime of RGB sub-pixels helps obtaining the OLED panel having long lifetime for RGB, thereby the lifetime of the OLED display panel can be increased.

Therefore in the present embodiment, the material of the third electron transport layer 73 uses PO₁₄ which is most beneficial to the lifetime of the blue sub-pixel, and the material of the first electron transport layer 71 and the material of the second electron transport layer 72 are both TPBI, and of course the first electron transport layer 71 may use the material different from the second electron transport layer 72, which does not affect the purpose of the present invention.

The following further illustrates the present invention combined with experimental data.

Electron transport material layers use two materials ETL01 and ETL02.

Photoelectric properties of the blue device under the current density of 15 mA/cm², the green device under 12000 nits and the red device under 3000 nits are as follows.

| color | | | current | | | |
|---|---|---|---|---|---|---|
| of | | drive | efficiency/ | | | |
| device | material | voltage/V | cd/A | CIE-x | CIE-y | LT95/hour |
| blue | ETL1 | 4.30 | 7.32 | 0.1295 | 0.0657 | 128 |
| | ETL2 | 4.54 | 6.52 | 0.1294 | 0.0655 | 416 |
| green | ETL1 | 4.0 | 100.3 | 0.1850 | 0.7363 | 244 |
| | ETL2 | 4.33 | 85.59 | 0.2002 | 0.7279 | 180 |
| red | ETL1 | 3.36 | 61.90 | 0.6576 | 0.3421 | 1200 |
| | ETL2 | 3.41 | 57.02 | 0.6640 | 0.3357 | 1300 |

The above table shows that using the ETL2 is in favor of enhancing the lifetime of the blue device, and the lifetime of the green device is better when using the ETL1 rather than the ETL2, and the lifetime of the red device is changeless no matter use the ETL1 or the ETL2; therefore RGB sub-pixels may use different materials for the ETL according to the actual requirement, so as to achieve RGB sub-pixels all having long lifetime.

In conclusion, the present invention discloses an OLED display panel with an improved lifetime of blue sub-pixel of OLED display panel, which is achieved by configuring an electron cushion layer between the blue sub-pixel light emitting layer and the electron transport layer to prevent the accumulation of electrons on the interface of the emitting layer, thus the lifetime of the blue sub-pixel of the OLED panel and the phenomenon of offset of white chromaticity coordinate of the OLED display panel caused by excessive attenuation of luminance of the blue sub-pixel are improved, so that the lifetime of the OLED display panel is increased; further the present invention uses different materials of the electron transport layer through RGB sub-pixels, by virtue of selecting the material of the electron transport layer which is most favorable to the lifetime of RGB sub-pixels according to the material of each sub-pixel light emitting layer, to improve the lifetime of the blue sub-pixel of the OLED panel and improve the phenomenon of offset of white chromaticity coordinate of the OLED display panel caused by excessive attenuation of luminance of the blue sub-pixel, so that the lifetime of the OLED display panel is increased.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An OLED display panel, comprising:
a luminescent material layer and an electron transport layer positioned on the luminescent material layer, wherein the luminescent material layer comprises a red sub-pixel light emitting layer, a green sub-pixel light emitting layer and a blue sub-pixel light emitting layer; and
an electron cushion layer disposed between the blue sub-pixel light emitting layer and the electron transport layer to limit accumulation of electrons between the blue sub-pixel light emitting layer and the electron transport layer.

2. The OLED display panel according to claim 1, wherein a material of the electron cushion layer is organic material.

3. The OLED display panel according to claim 1, wherein a material of the electron cushion layer is the same as host material of the electron transport layer.

4. The OLED display panel according to claim 1, wherein thickness of the electron cushion layer is between 5 angstroms to 500 angstroms.

5. The OLED display panel according to claim 1 further comprising:
a substrate, an anode, a hole injection layer, a hole transport layer, an electron injection layer and a cathode;
wherein the anode is positioned between the substrate and the hole injection layer, the hole transport layer is positioned between the hole injection layer and the luminescent material layer, the electron injection layer covers an upper surface of the electron transport layer, and the cathode covers an upper surface of the electron injection layer.

6. The OLED display panel according to claim 1, wherein a material of the blue sub-pixel light emitting layer is fluorescent material, and a material of the green sub-pixel light emitting layer and a material of the red sub-pixel light emitting layer are both phosphor material.

7. The OLED display panel according to claim 1, wherein FFM is used to manufacture the electron cushion layer.

8. An OLED display panel, comprising: a luminescent material layer and an electron transport material layer positioned on the luminescent material layer; the luminescent material layer comprising a red sub-pixel light emitting layer, a green sub-pixel light emitting layer and a blue sub-pixel light emitting layer;
wherein the electron transport material layer comprises a first electron transport layer covering an upper surface of the red sub-pixel light emitting layer, a second electron transport layer covering an upper surface of the green sub-pixel light emitting layer and a third electron transport layer covering an upper surface of the blue sub-pixel light emitting layer;
wherein a material of the third electron transport layer is different from materials of the first electron transport layer and/or second electron transport layer.

9. The OLED display panel according to claim 8, wherein the material of the first electron transport layer is the same as the material of the second electron transport layer.

10. The OLED display panel according to claim 8, wherein a material of the blue sub-pixel light emitting layer is fluorescent material, and a material of the green sub-pixel light emitting layer and a material of the red sub-pixel light emitting layer is phosphor material.

11. The OLED display panel according to claim 10, wherein the material of the third electron transport layer is PO₁₄.

12. The OLED display panel according to claim 10, wherein the material of the first electron transport layer and the material of the second electron transport layer are both TPBI.

13. The OLED display panel according to claim 8, further comprising:
a substrate, an anode, a hole injection layer, a hole transport layer, an electron injection layer and a cathode;
wherein the anode is positioned between the substrate and the hole injection layer, the hole transport layer is positioned between the hole injection layer and the luminescent material layer, the electron injection layer covers an upper surface of the electron transport layer, and the cathode covers an upper surface of the electron injection layer.
